(19) United States
(12) Patent Application Publication
(10) Pub. No.: US 2011/0001185 A1
(43) Pub. Date: Jan. 6, 2011

(54) DEVICE

(75) Inventor: Noriaki MIKASA, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/796,941

(22) Filed: Jun. 9, 2010

(30) Foreign Application Priority Data
Jul. 3, 2009 (JP) 2009-158345

(51) Int. Cl. H01L 29/78

(52) U.S. Cl. 257/327; 257/E29.255

(57) ABSTRACT

A semiconductor device includes a first diffusion region and a second diffusion region in an active region surrounded by an isolation insulation region, a recessed trench region formed between the first diffusion region and the second diffusion region, a gate insulation film formed on the trench region, a gate electrode formed on the gate insulation film to fill the trench region therewith, and a protection insulation film formed in an upper part of the region interposed between the gate insulation film and the isolation insulation region.

This application is based upon and claims the benefit of priority from Japanese patent application No. 2009-158345, filed on Jul. 3, 2009, the disclosure of which is incorporated herein in its entirety by reference.

### BACKGROUND OF THE INVENTION

1. Field of the Invention

This invention relates to a device and a manufacturing method thereof, and in particular relates to a semiconductor device having a field-effect transistor and a manufacturing method thereof.

2. Description of the Related Art

High degree integration of semiconductor devices requires size reduction of transistors. However, when an attempt is made to reduce the size of a planar field-effect transistor, a short-channel effect will occur due to reduced gate width. Furthermore, the channel region width also will be reduced, causing a problem of reduced drive current. Therefore, it is difficult to reduce the size of planar field-effect transistors.

Known methods for enabling reduction of the transistor sizes without inducing the problems described above include a method in which a transistor is configured in a three-dimensional structure. For example, a trench gate structure in which a gate electrode is embedded in a silicon substrate can be employed to enlarge the gate width. A fin-type structure in which an active region is formed into a thin wall shape can be employed to enlarge the channel width.

Japanese Laid-Open Patent Publication No. 2005-57293 (Patent Document 1) discloses a semiconductor device which employs a combination of the trench gate structure and the fin-type structure. This semiconductor device has a projecting part of an active region interposed between an isolation insulation region and a trench region, and a gate insulation film and a gate electrode which are formed to traverse the projecting part. This projecting part is used as a channel region.

### SUMMARY

In the semiconductor device disclosed in Patent Document 1, a gate insulation film and a gate electrode are formed to traverse the projecting part. This means that the gate insulation film is formed to cover from the top face of the projecting part to the opposite side walls, and the gate electrode is formed on the gate insulation film. According to this configuration, the periphery of an upper part the projecting part is surrounded by the gate electrode with a gate oxide film interposed therebetween. The present inventor has recognizes that when a voltage is applied to the gate electrode, there are simultaneously generated, near the upper tip end of the projecting part, an electric field from the gate electrode on the side wall side and an electric field from the gate electrode on the top face side. This means that the electric field generated in this configuration is increased in a manner concentrated particularly to the vicinity of the tip end of the projecting part, possibly resulting in deterioration of dielectric voltage of the gate oxide film and eventually dielectric breakdown.

The present invention seeks to solve one or more of the above problems, or to improve upon those problems at least in part.

In one embodiment, there is provided a device that includes a first diffusion region and a second diffusion region formed in an active region surrounded by an isolation insulation region. A trench region has a recess formed between the first diffusion region and the second diffusion region. A gate insulation film is formed on the trench region. A gate electrode is formed on the gate insulation film to fill the trench region therewith. A protection insulation film is formed in an upper part of the region interposed between the gate insulation film and the isolation insulation region.

Provision of a protection insulation film on the upper side of a region interposed between the gate insulation film and the isolation insulation region increases the distance between the top face of the active region located in the lower side of that region and the gate insulation film and gate electrode, whereby the local concentration of the electric field in the active region is prevented. If the electric field is blocked from the top face, the channel region width will be decreased by that much and the drive current of the transistor will be reduced. However, the occupancy of the top face to the total width of the channel region is rather low and the occupancy will be decreased along with further downsizing of semiconductor devices in the future. Therefore, even if a semiconductor device is configured such that the electric field is not generated from the top face of the channel region like the one according to an embodiment of the invention, the drive current of the transistor will not change significantly in comparison with the case in which the electric field is generated from the top face.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a flowchart for explaining manufacturing steps of a semiconductor device according to a first embodiment of the invention;

FIGS. 2A to 2C are diagrams showing a state after completion of one of the manufacturing steps of the semiconductor device according to the first embodiment of the invention, FIG. 2A being a plan view, FIG. 2B being a cross-sectional view taken along the line B-B, FIG. 2C being a cross-sectional view taken along the line C-C;

FIGS. 3A to 3C are diagrams showing a state after completion of a step after the step shown in FIGS. 2A to 2C, FIG. 3A being a plan view, FIG. 3B being a cross-sectional view taken along the line B-B, FIG. 3C being a cross-sectional view taken along the line C-C;

FIGS. 4A-4C are diagrams showing a state after completion of a step after the step shown in FIGS. 3A to 3C, FIG. 4A being a plan view, FIG. 4B being a cross-sectional view taken along the line B-B, FIG. 4C being a cross-sectional view taken along the line C-C;

FIGS. 5A to 5C are diagrams showing a state after completion of a step after the step shown in FIGS. 4A-4C, FIG. 5A being a plan view, FIG. 5B being a cross-sectional view taken along the line B-B, FIG. 5C being a cross-sectional view taken along the line C-C;

FIGS. 6A to 6C are diagrams showing a state after completion of a step after the step shown in FIGS. 5A to 5C, FIG. 6A being a plan view, FIG. 6B being a cross-sectional view taken along the line B-B, FIG. 6C being a cross-sectional view taken along the line C-C;

FIGS. 7A to 7C are diagrams showing a state after completion of a step after the step shown in FIGS. 6A to 6C, FIG. 7A being a plan view, FIG. 7B being a cross-sectional view taken along the line B-B, FIG. 7C being a cross-sectional view taken along the line C-C;

FIGS. 8A to 8C are diagrams showing a state after completion of a step after the step shown in FIGS. 7A to 7C, FIG. 8A being a plan view, FIG. 8B being a cross-sectional view taken along the line B-B, FIG. 8C being a cross-sectional view taken along the line C-C;

FIGS. 9A-9C are diagrams showing a state after completion of a step after the step shown in FIGS. 8A to 8C, FIG. 9A being a plan view, FIG. 9B being a cross-sectional view taken along the line B-B, FIG. 9C being a cross-sectional view taken along the line C-C; and

FIGS. 10A-10C are diagrams showing a state after completion of a step after the step shown in FIGS. 9A to 9C, FIG. 10A being a plan view, FIG. 10B being a cross-sectional view taken along the line B-B, FIG. 10C being a cross-sectional view taken along the line C-C.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In the following, a DRAM (Dynamic Random Access Memory) is used as an example of devices, and description will be made of a manufacturing process of a transistor such as a MOSFET (Metal Oxide Semiconductor Field Effect Transistor) used in the DRAM.

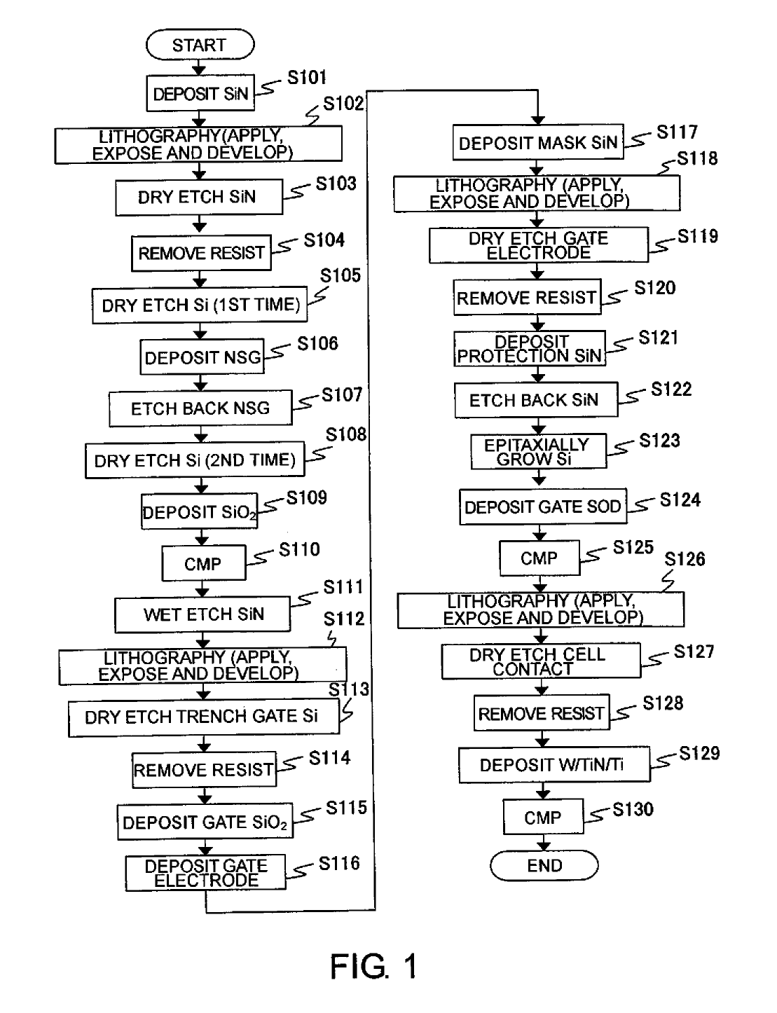

FIG. 1 is a flowchart for explaining a first example of a manufacturing process of a MOSFET. It should be noted that this flowchart shows only steps of forming principal components (e.g. STI (Shallow Trench Isolation), gate electrode, and cell contact), while omitting the steps of impurity diffusion and so on which can be performed by using the known methods.

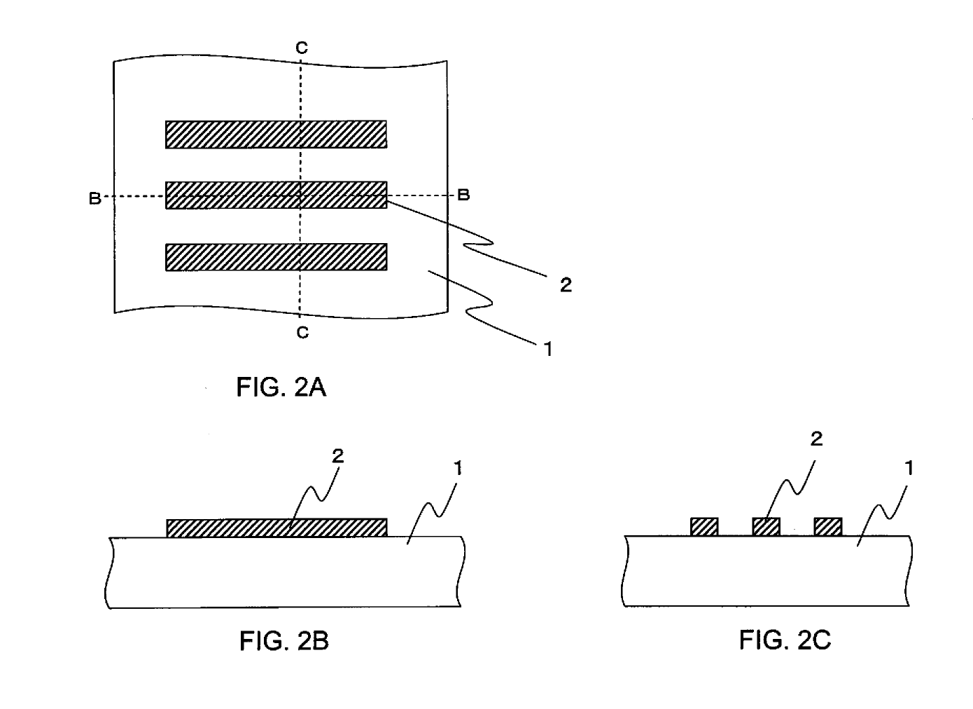

Referring to FIGS. 2A to 2C through FIGS. 10A to 10C in addition to FIG. 1, a transistor manufacturing process will be described in detail.

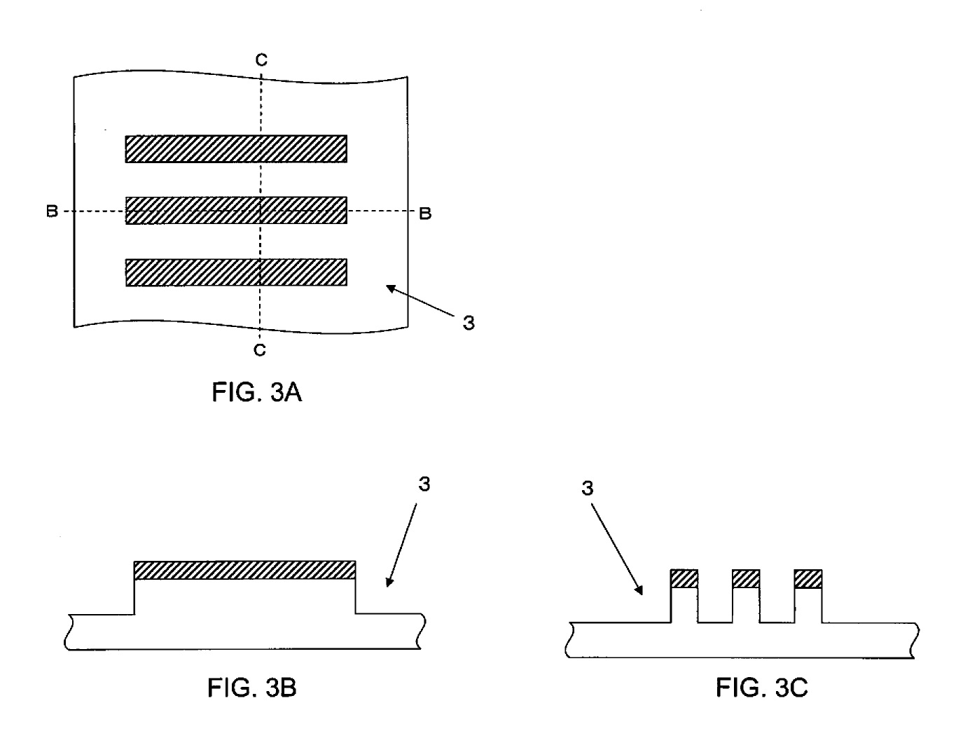

As shown in FIGS. 2A to 2C, a silicon nitride (SiN) film 2 is formed into a predetermined shape on a silicon (Si) substrate 1. FIG. 2A is a plan view showing a region corresponding to a unit cell of a transistor, FIG. 2B is a cross-sectional view taken along the line B-B in FIG. 2A, and FIG. 2C is a cross-sectional view taken along the line C-C in FIG. 2A. The same applies to the drawings of FIGS. 3A to 3C onwards. Specifically, FIG. A are plan views showing a region corresponding to a unit cell of a transistor, FIG. B are cross-sectional views taken along the line B-B in FIG. A, and FIG. C are cross-sectional views taken along the line C-C in FIG. A.

The silicon nitride film 2 with a predetermined shape shown in FIGS. 2A to 2C is formed as described below.

Firstly, a silicon substrate 1 is prepared and a silicon nitride film 2 is formed on the whole surface thereof (step S101). This silicon nitride film 2 is formed to a thickness of 100 nm by a decompression CVD method, for example.

Then, a resist film of a predetermined shape is formed on the silicon nitride film 2 by using a lithography technique (step S102). Specifically, resist is applied, exposed to light, and developed, whereby a resist film having a predetermined shape is formed. This predetermined shape corresponds to the shape of each active region 7 to be described later.

Subsequently, the silicon nitride film 2 is dry etched with the resist film on the silicon nitride film 2 used as a mask, so that the mask pattern is transferred to the silicon nitride film 2 (step S103). Then, the resist film is removed (step S104).

As a result of the processing steps described above, the silicon nitride film 2 having the predetermined shape is formed on the silicon substrate 1. The silicon nitride film 2 having the predetermined shape is located on each active region of the silicon substrate 1. In this embodiment of the invention, it is assumed that a plurality of (three in this example) active regions having the same shape are arranged in parallel with each other within a unit cell region of the transistor.

In the next step, the silicon substrate 1 is dry etched with the silicon nitride film 2 used as a mask, whereby a trench region (STI) 3 is formed as shown in FIGS. 3A to 3C (step S105). This dry etching is performed to a depth of 65 nm, for example. The dry etching may be performed by reactive ion etching (RIE) using inductively coupled plasma (ICP). In this case, the etching conditions can be set such that the source power is 1000 W, the high-frequency power is in the range of 50 to 200 W, the pressure is in the range of 5 to 20 mTorr, the stage temperature is in the range of 20 to 40° C., and the etching gas is SF₆ (90 sccm) and Cl₂ (100 sccm).

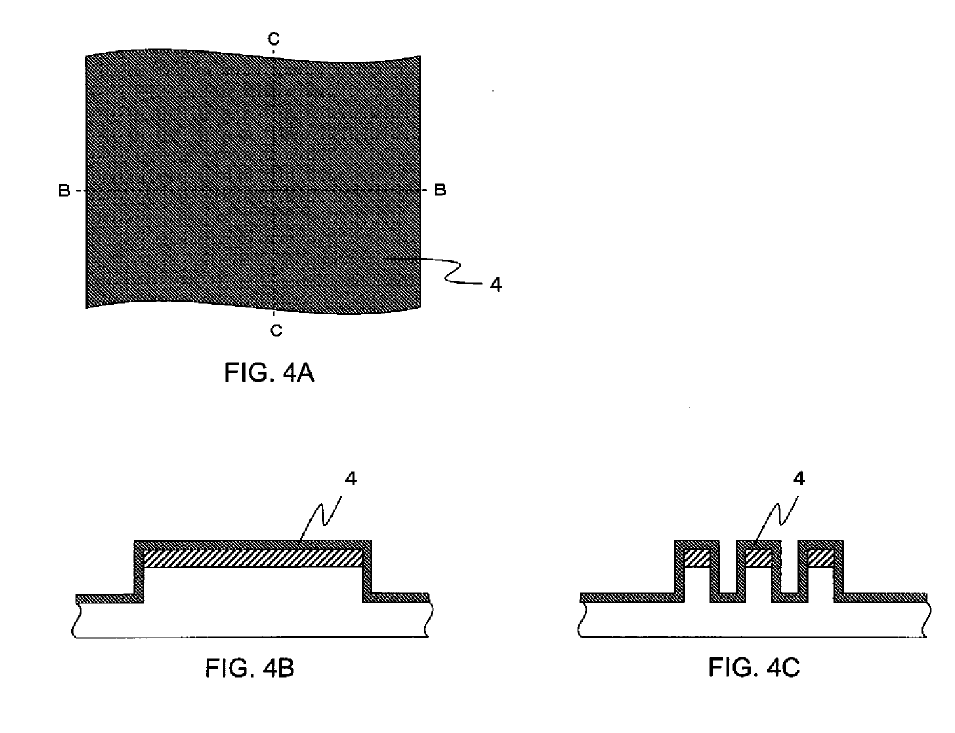

In the next step, a non-doped silicate grass film (NSG) 4 is deposited to cover the whole exposed surfaces of the silicon substrate 1 and silicon nitride film 2, as shown in FIGS. 4A to 4C (step S106). As a result of this, the side faces of the trench region 3 (the side faces of the active regions of the silicon substrate 1 and the side faces of the silicon nitride film 2) are also covered with the non-doped silicate glass film 4. The non-doped silicate glass film 4 is formed to a thickness of 15 nm, for example, by a decompression CVD method.

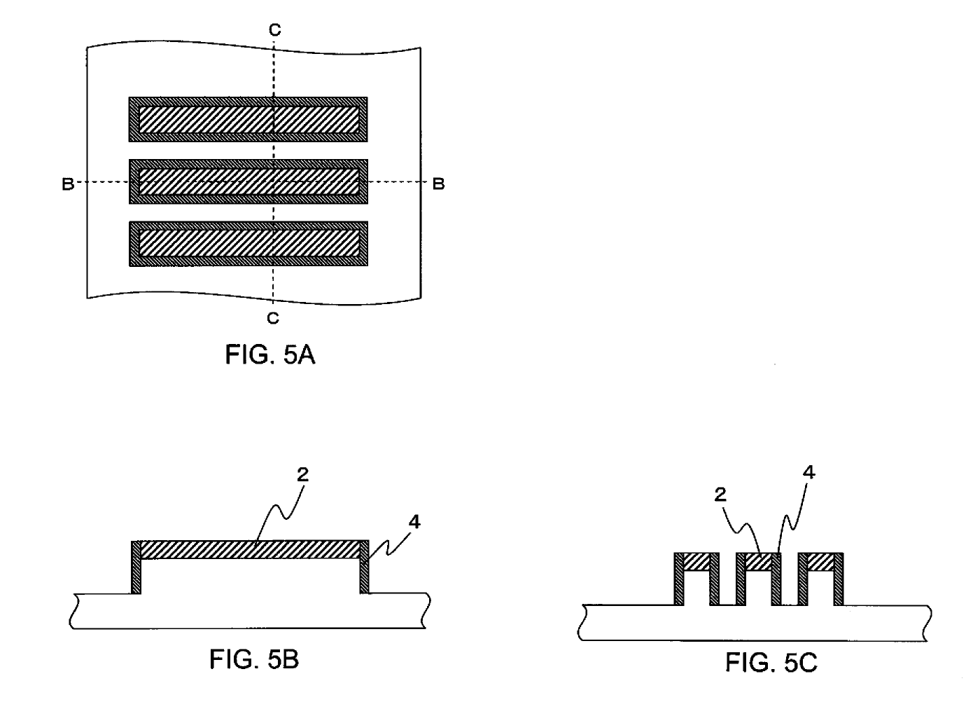

In the next step, the non-doped silicate glass film 4 is etched back so that, as shown in FIGS. 5A to 5C, the non-doped silicate glass film 4 on the top of the silicon substrate 1 and silicon nitride film 2 is removed while leaving the non-doped silicate glass film 4 on the side faces of the trench region 3 (step S107).

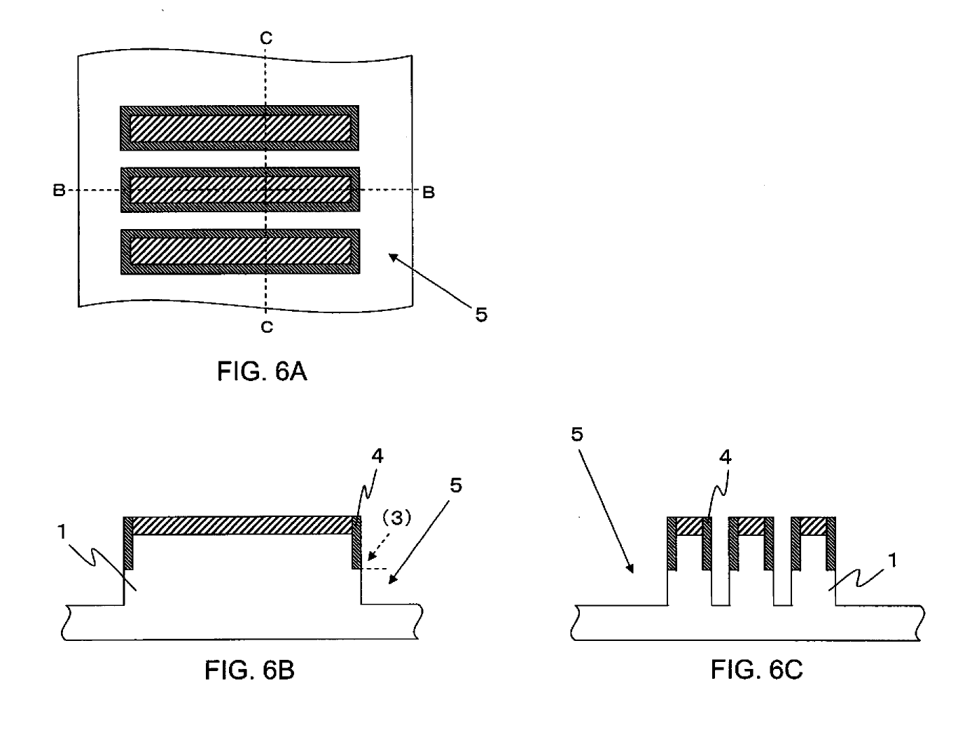

In the next step, dry etching is performed with the silicon nitride film 2 and the non-doped silicate glass film 4 used as a mask so that, as shown in FIGS. 6A to 6C, the depth of the trench region 3 is increased to form a trench region 5 serving as an isolation insulation region (step S108). This dry etching can be performed under the same conditions as in step S105. The etching depth is 65 nm, for example. When the etching depth in step S105 and the etching depth in step S108 are both 65 nm, the total depth becomes 130 nm.

As seen from FIGS. 6B and 6C, the silicon substrate 1 is not etched but remains as it is under the non-doped silicate glass film 4 left on the side faces of the trench region 3. As a result, as shown in FIG. 6C, the side faces of the remaining portions of the silicon substrate 1 and the non-doped silicate glass film 4 defining the trench region 5 become bilaterally symmetric. These remaining portions of the silicon substrate 1 are the regions to be utilized as channel regions as clarified later. Accordingly, if these portions are not bilaterally symmetric, it will cause variation in characteristics of a semiconductor device to be manufactured later.

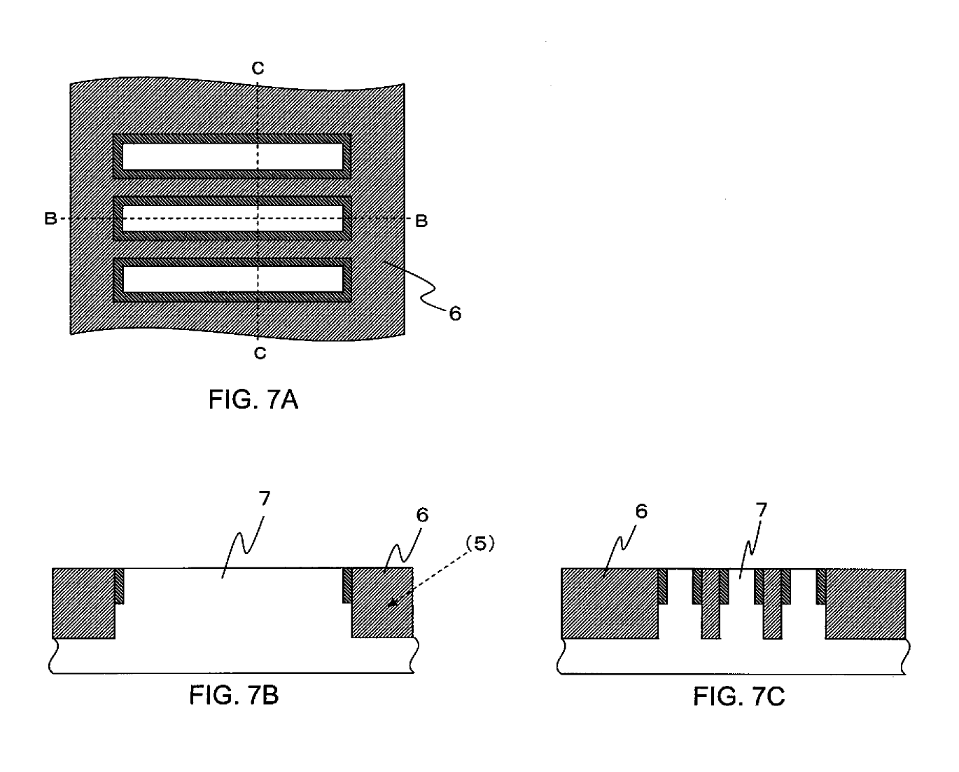

In the next step, as shown in FIGS. 7A to 7C, the trench region 5 is embedded with a silicon oxide (SiO₂) film 6 while the top faces of the active regions 7 are exposed.

First, the silicon oxide film 6 is deposited on the whole surface in order to embed the trench region 5 (step S109). The trench region 5 can be embedded by forming a SiO₂ film with a thickness of 480 nm by a plasma CVD method, for example.

In the next step, CMP (Chemical Mechanical Polishing) is performed on the silicon oxide film 6 using the silicon nitride film 2 left on the active regions 7 in the silicon substrate 1 as a stopper, whereby the unnecessary SiO₂ is removed (step S110).

After that, the residual silicon nitride film 2 is removed by wet etching using phosphoric acid, for example, so that the top faces of the active regions 7 are exposed (step S111). The silicon oxide film 6 filling the trench region 5 also can be wet etched using diluted hydrofluoric acid so that the top faces of the active region 7 are made flush with the top face of the silicon oxide film 6.

Thus, as shown in FIGS. 7A to 7C, a structure can be obtained in which the trench region 5 is embedded in the silicon oxide film 6 and the top faces of the active regions 7 are exposed.

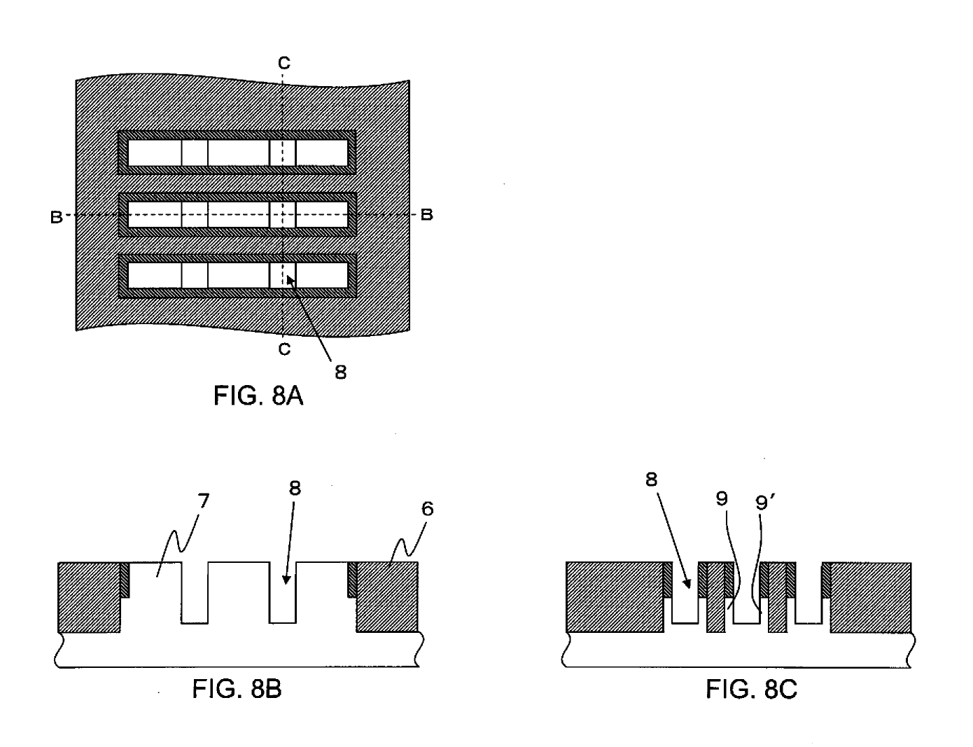

In the next step, as shown in FIGS. 8A to 8C, a pair of gate trenches 8 is formed in each of the active regions 7. Formation of the gate trenches 8 is carried out in the following manner, for example.

Firstly, a resist film is formed on the surfaces of the silicon oxide film 6 and active regions 7. Subsequently, a lithography technique is used to form openings in the regions of the resist film corresponding to the gate trenches to be formed (step S112). Then, dry etching is performed with this resist film used as a mask so that trenches (gate trenches 8) are formed in the respective corresponding parts of the active regions 7 (step S113). After that, the resist film is removed (step S114).

In this manner, a pair of gate trenches 8 is formed in each of the active regions 7, as shown in FIGS. 8A to 8C. The gate trenches 8 have a depth of 65 nm, for example.

In FIGS. 8A and 8B, the region located at the center of each active region, in other words, the region interposed between a pair of gate trenches 8 constitutes a source region (first diffusion region). In the same figures, the regions located on the opposite ends of the active region 7 constitute drain regions (second diffusion regions). In this manner, each of the gate trenches 8 is formed in a groove shape between the first diffusion region and one of the pair of second diffusion regions.

As shown in FIG. 8C, each of the active regions 7 assumes a recessed shape in cross-section in a region located between the first diffusion region and each of the second diffusion regions. This means that a pair of protruding portions (fins) 9, 9′ are formed to face each other across the gate trench 8 with a distance. These protruding portions 9, 9′ are utilized as channel regions. There exists on each of the protruding portions 9, 9′, the non-doped silicate glass film 4 having substantially the same shape (fin shape) as that of the protruding portions 9, 9′ and serves as an insulation film. Desirably, the gate trenches 8 should be formed shallower than the trench region 5, that is, such that the bottoms of the gate trenches 8 are located at a higher level than the lower surface of the silicon oxide film 6.

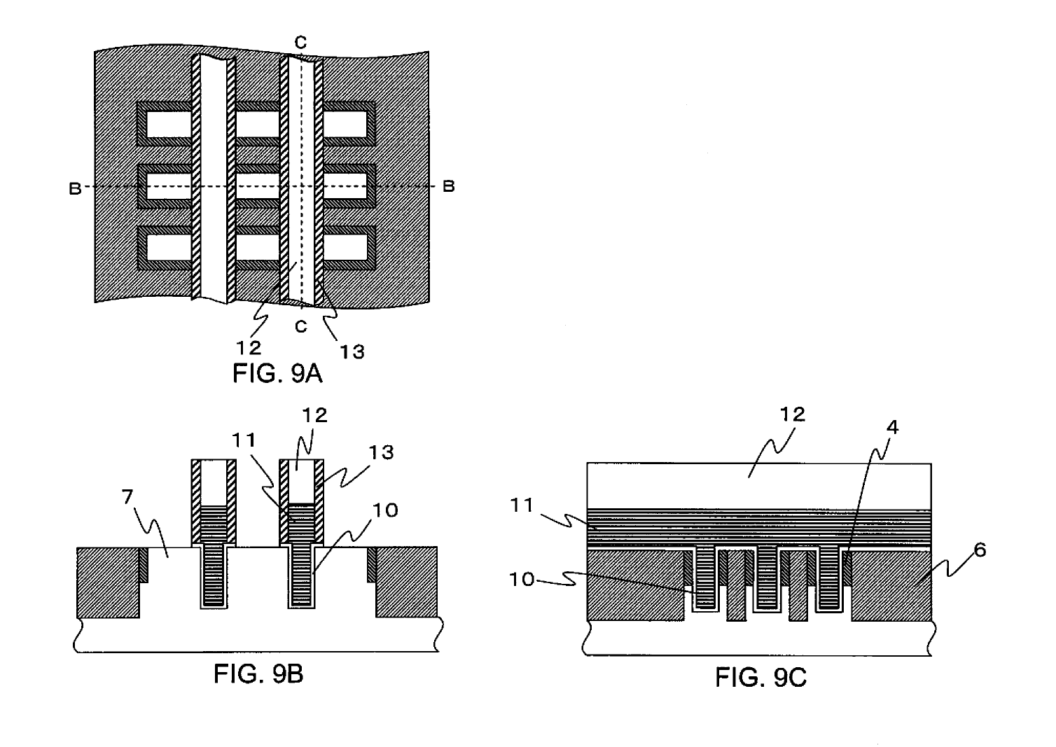

In the next step, gates are formed as shown in FIGS. 9A to 9C. Formation of the gates is carried out as described below.

Firstly, a gate oxide film (SiO₂ film) 10 is deposited to a thickness of 2 to 6 nm (step S115) and, subsequently, gate electrodes 11 are formed (step S116). The gate electrodes 11 can be formed, for example, by stacking a 60 nm thick DOPS (Doped Poly Silicon) film and a 35 nm thick tungsten film.

Then, a mask silicon nitride film 12 is deposited for example to a thickness of 200 nm (step S117). The mask silicon nitride film 12, the gate electrodes 11 and the gate oxide film 10 are formed into a predetermined shape by lithography and dry etching using resist (steps S118 and S119). The resist is then removed (step S120).

In this manner, the gate oxide film 10 serving as a gate insulation film is formed on the gate trench region. In other words, the gate insulation film is formed to cover the surfaces of the active regions 7 defining the gate trenches 8 including the side faces of the protruding portions 9, 9′ and the side faces and top faces of the non-doped silicate glass films 4 on the top of the protruding portions 9, 9′. Further, the gate electrodes 11 are formed on the gate insulation film so as to fill the gate trench region. As a result, as shown in FIG. 9C, the non-doped silicate glass film 4 exists as a protection insulation film in an upper part of each region between the gate insulation film (gate oxide film 10) and the isolation insulation region (silicon oxide film 6). The lower part of the each region serves as a channel region.

Subsequently, a protection silicon nitride film 13 is formed for example to a thickness of 20 to 30 nm (step S121), and then is etched back so that the protection silicon nitride film 13 is left on the side walls of the gates (step S122).

As a result of the steps described above, the gates are formed to traverse the plurality of active regions 7.

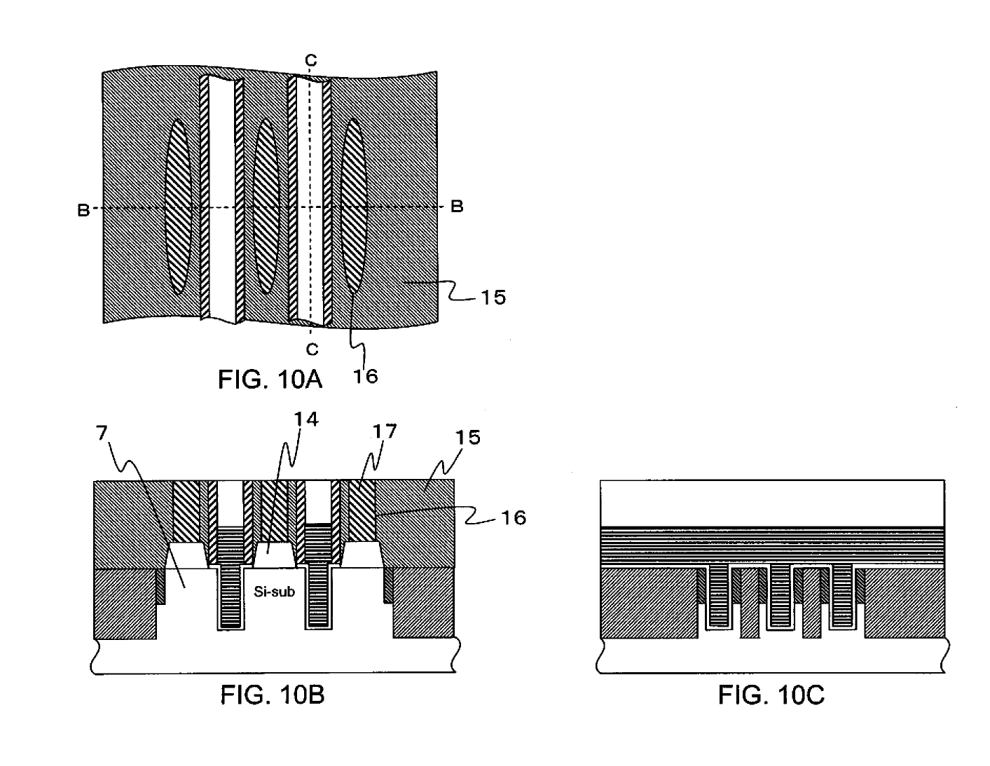

In the next step, as shown in FIGS. 10A to 10C, formation of a source electrode, a drain electrode and so on is performed.

Firstly, a silicon epitaxial layer 14 is grown to a thickness of 20 to 30 nm on the active region 7 (step S123).

Next, a SOD (Spin On Dielectrics) film 15 is formed for example to a thickness of 400 nm (step S124), and then an unnecessary part of the SOD film 15 is removed by performing CMP with the mask silicon nitride film 12 used as a stopper (step S125).

Next, cell contact holes 16 are formed in the SOD film 15 by lithography and dry etching using resist (steps S126 to S127). The resist is then removed (step S128).

Subsequently, contact plugs 17 are formed in the respective cell contact holes 16. The contact plugs 17 can be formed by stacking layers of titanium, titanium nitride and tungsten. For example, a 10 nm thick titanium layer, a 10 nm thick titanium nitride layer, and a 100 nm thick tungsten layer are successively formed (step S129), and then unnecessary parts of the tungsten, titanium nitride and titanium layers are removed by CMP (step S130). In this manner, the contact plugs 17 are formed in the respective cell contact holes 16.

A semiconductor device is manufactured by the manufacturing steps as described above.

The semiconductor device according the embodiment of the invention has a protection insulation film (non-doped silicate glass film 4) in an upper part of the region interposed between the gate insulation film (gate oxide film 10) and the isolation insulation film (silicon oxide film 6). Therefore, when a voltage is applied from the gate electrodes 11 to the protruding portions 9, 9′, at least generation of electric field from the top faces of the protruding portions 9, 9′ is prevented. As a result, the electric field generated in the protruding portions 9, 9′ can be reduced, whereby problems attributable to concentration of the electric field can be solved.

Further, in the semiconductor device according to the embodiment of the invention, a plurality of active regions 7 are formed in parallel within a unit cell. Therefore, there exists a plurality of channel regions in parallel between the first diffusion region and the second diffusion region. This makes it possible to increase the transistor drive current by simultaneously using this plurality of channel regions.

Although this invention has been described in conjunction with a few preferred embodiments thereof, this invention is not limited to the foregoing embodiments but may be modified and changed in various other manners without departing from the scope and spirit of the invention. For example, although the embodiments above have been described of a case in which three active regions are provided within a unit cell, the number of the active regions is not limited to three but may be one, two, or four or more. Further, this invention is also applicable to a transistor having one second diffusion region with respect to one first diffusion region. Furthermore, the materials of the components are not limited to the examples described above but various other materials can be used.

In addition, this invention provides a device manufacturing method as following exemplary notes.

Exemplary note 1. A manufacturing method of a device comprising:

etching a silicon substrate to form a trench region;

forming an insulation film on the side faces of the trench region; and

further etching the silicon substrate with the insulation film left on the side faces to increase the depth of the trench region.

Exemplary note 2. The manufacturing method of the exemplary note 1, wherein the silicon substrate is partially etched at a region different from the trench region to form the fin portion under the insulation film.

What is claimed is:

1. A device comprising:
a first diffusion region and a second diffusion region formed in an active region surrounded by an isolation insulation region;
a trench region having a recess formed between the first diffusion region and the second diffusion region;
a gate insulation film formed on the trench region;
a gate electrode formed on the gate insulation film to fill the trench region therewith; and
a protection insulation film formed in an upper part of the region interposed between the gate insulation film and the isolation insulation region.

2. The device as claimed in claim 1, further comprising a channel region formed in a lower part of the region interposed between the gate insulation film and the isolation insulation region.

3. The device as claimed in claim 1, wherein the second diffusion region is provided on the opposite sides of the first diffusion region, respectively.

4. The device as claimed in claim 1, wherein the active region is provided in plurality in parallel within a unit cell of a transistor.

5. A device comprising:
a fin portion formed in an active region;
a protection insulation film having a fin shape provided on the fin portion;
a gate insulation film formed to cover from the side face of the fin portion and protection insulation film to the top face of the protection insulation film; and
a gate electrode formed on the gate insulation film.

6. The device as claimed in claim 5, wherein the fin portion is provided in a pair such that the pair of fin portions face each other across a distance.

7. The device as claimed in claim 5, wherein the top face of the fin portions is located at a lower level than the top face of the active region.

8. The device as claimed in claim 7, wherein the side faces of the fin portion and the protection insulation film define a part of a gate trench, and the gate electrode is formed to fill the gate trench therewith.

9. The device as claimed in claim 5, comprising a first diffusion region and a second diffusion region within the active region, wherein the fin portion is provided between the first diffusion region and the second diffusion region.

10. The device as claimed in claim 9, wherein the fin portion is used as a channel region.
